(19) United States
(12) Patent Application Publication
(10) Pub. No.: US 2006/0040104 A1
(43) Pub. Date: Feb. 23, 2006

(54) Heat spreader

(76) Inventors: Christopher John Howard Wort, Oxfordshire (GB); Charles Simon James Pickles, Twickenham (GB)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/529,633

(22) PCT Filed: Oct. 8, 2003
(86) PCT No.: PCT/IB03/04420

§ 371 Date: Aug. 26, 2005

(30) Foreign Application Priority Data
Oct. 8, 2002 (GB) 0223321.1

(51) Int. Cl. C23C 16/26; B32B 9/00

(52) U.S. Cl. 428/408; 427/249.1

(57) ABSTRACT

A heat spreader for an electronic device has a layer of CVD diamond, which is continuous and without uncontrolled pits or holes, grown onto a diamond loaded material. The diamond loaded material includes a mass of diamond particles in a matrix and has a surface with exposed diamond particles on which the layer of CVD diamond is grown. The layer of CVD diamond is bonded to the exposed diamond particles of the diamond loaded material at least in part by epitaxy.

### BACKGROUND OF THE INVENTION

This invention relates to heat spreaders.

Thermal management materials can be divided into two distinct groups. The first is heat sinks and the second is heat spreaders. A heat sink is used to remove heat from an object or closed system, such as is the case with heat transfer into a metal block which then passes the heat into ambient air or a water cooling circuit. A heat spreader, on the other hand, is used to rapidly conduct heat away from a local “hot spot” into the bulk of the heat spreader. The heat spreader is normally in thermal contact with a heat sink for removal of the heat generated entirely from the system.

Heat flow follows the principle of conservation of flux, wherein the total heat flux across any surface enclosing the source is the same. Closer to the heat source the surface area is smaller and thus if the material had uniform thermal conductivity the temperature gradient would be larger. Consequently there is considerable benefit in having a high thermal conductivity heat spreader in that region.

Heat is conducted by two main mechanisms, electronic transfer and lattice vibrations. In most good thermal conductors, the dominant mechanism is electronic transfer, where hot electrons are free to disperse and carry heat with them. The movement of these electrons also makes these materials good electrical conductors. In a more limited group of materials, the thermal conduction arises from phonon transfer in the lattice, and these materials can be electrical insulators. Many heat management applications benefit from, or require, the use of a heat spreader material that is an electrical insulator, for example where the cooled object is an electronic device where the mounting face forms one of the electrical contacts.

Heat sinks are thus often metallic in nature and electrically conducting. As they are used to remove heat from a relatively large surface area, the power density is low and thus the thermal conductivity of many metals, for example aluminium or copper, is acceptable.

Heat spreaders, on the other hand, rely totally on their ability to remove heat from local “hot spots” and their thermal conductivity is vitally important. Materials such as Si, SiC, Cu, Al and Ag are good heat spreaders in their own right, and in many cases can be fabricated into even better heat-spreaders when the bulk material is loaded with diamond crystals thus forming a composite material. By varying the diamond proportion in the composite both the thermal conductivity and the average thermal expansion coefficient can be tailored to the application. However all these materials electrically conduct, at least to some degree, even in the form of a diamond loaded composite, and this limits their application.

Diamond, and in particular CVD diamond, is extremely attractive as a heat spreader. Diamond has a very stiff, rigid lattice and a very wide band gap, resulting in excellent thermal conduction by phonon transfer and extremely good electrical insulation. However, heat spreaders are required in applications which are very price sensitive, and often solid diamond layers cannot be produced at the required cost.

Other materials which are also electrically insulating and which can be used as heat spreaders are alumina, beryllia, aluminium nitride and boron nitride. However, compared to diamond these materials have a much lower thermal conductivity, and a significantly lower thermal conductivity than the better diamond loaded composite materials described earlier.

### SUMMARY OF THE INVENTION

According to the present invention, a heat spreader, particularly for an electronic device, comprises a layer of CVD diamond, which is preferably continuous and without uncontrolled pits or holes, grown onto a diamond loaded material, which comprises a mass of diamond particles in a matrix and has a surface with exposed diamond particles on which the layer of CVD diamond is grown, wherein the layer of CVD diamond is bonded to the exposed diamond particles of the diamond loaded material at least in part by epitaxy. The diamond loaded material will hereafter be referred to as “DL material”.

Preferably, the heat spreader exhibits substantial epitaxy at the interface between the layer of CVD diamond and the exposed diamond particles of the DL material. In particular, the epitaxy preferably covers an area of the interface exceeding 30%, more preferably exceeding 50%, even more preferably exceeding 60% and even more preferably exceeding 70%.

The CVD diamond layer preferably has an exposed surface with at least 30%, preferably at least 50%, more preferably at least 60% and even more preferably at least 70% of the exposed surface being occupied by diamond grains with a grain size of at least four times the thickness of the layer of CVD diamond

Epitaxial diamond grains preferably provide at least 30%, more preferably at least 50%, even more preferably at least 60% and even more preferably at least 70%, of the CVD diamond layer.

Preferably, the bonding by epitaxy between the layer of CVD diamond and the diamond particles of the DL material is deliberately enhanced over that which might occur naturally using untreated DL material.

The DL material will generally be provided in the form of a layer with the layer of CVD diamond being grown on a major surface of the layer of DL material.

According to a further aspect of the invention, a heat spreader comprises a layer of DL material having major surfaces on each of opposite sides thereof, and a layer of CVD diamond in thermal contact with each of the major surfaces, with either one or both of the CVD diamond layers being bonded at least in part by epitaxy to exposed diamond particles of the DL material, and preferably where this bonding by epitaxy between the layer(s) of CVD diamond and the diamond particles of the diamond loaded material is deliberately enhanced over that which might occur naturally using untreated DL material.

A further aspect of the invention is the use of surface preparation techniques and growth conditions for the growth of the CVD diamond layer such as to optimise the bonding by epitaxy between the CVD diamond layer and the diamond loading of the DL material.

In particular, the invention extends to a method of manufacturing a heat spreader including the steps of providing a diamond loaded (DL) material comprising a mass of diamond particles in a matrix and having an exposed surface with exposed diamond particles, growing a layer of CVD diamond onto the exposed surface of the DL material such that it is bonded to the exposed diamond particles at least in part by epitaxy, wherein the exposed surface of the DL material is treated prior to growing the layer of CVD diamond thereon, thereby to enhance the epitaxy over that which would otherwise occur naturally using untreated DL material.

The method preferably uses a lapping process for the treatment or preparation of the exposed surface of the DL material.

### DESCRIPTION OF EMBODIMENTS

The DL material can be any diamond loaded material, for example diamond loaded material where the matrix is Si, SiC, Cu, Al or Ag. Preferably, the matrix of the DL material is one of Si and SiC, and more preferably is SiC. The preferred matrix may be application specific, choosing a particular matrix with specific diamond loading to match the thermal expansion coefficient of the Si based devices that will be attached to the heat spreader. In this instance, the matrix may itself have a thermal expansion coefficient close to or larger than that of the Si devices, and the diamond loading selected to reduce the composite thermal expansion coefficient to suit. Preferably the diamond particles loading the material are greater than 10 μm in diameter, and are preferably synthetic Ib or natural IIa diamond. A mixture of diamond particle sizes is preferably used to ensure good loading of the DL material, although the precise size distribution can be tailored for the application.

The invention is particularly beneficial where the DL material provides a relatively high thermal conductivity, but insufficient electrical isolation on its own. The pin hole free CVD diamond layer bonded to the surface of the DL material then provides the electrical isolation, and its thickness is chosen to provide the isolation characteristics (voltage, leakage current) required by the application. Additionally, the diamond provides a surface which is much more easily planarised or provided with a high surface finish than that of the underlying diamond loaded material and can therefore be made more suitable for metallisation, photolithography and mounting of devices. Finally the diamond layer provides a layer of more uniform and higher thermal conductivity than the DL material in the critical area directly in contact with the device to be cooled.

Deposition directly onto unprepared DL material, which often has a rough surface, can lead to holes in the CVD diamond coating. These holes would form conductive pathways, negating the coating's function as an electrical isolator. The preparation techniques contained in the invention planarise and smooth the DL material surface to eliminate such holes.

Typical thicknesses of the diamond layer are 0.1 μm-300 μm, and preferably 1 μm-200 μm, and more preferably 2 μm-150 μm and even more preferably 10 μm-100 μm.

A problem with using multiple layers in heat spreaders, however, is the thermal impedance of the boundaries. This thermal impedance may arise as a result of degraded material at the boundaries, poor mechanical contact, phonon scattering due to thermal mismatch at the boundaries, and the like. Accordingly, in order to address this problem, this invention provides that when CVD diamond is synthesised onto a DL material, the preparation and growth conditions are chosen to enable or enhance the ability of the diamond to grow epitaxially on the diamond crystals present or exposed at the surface of the DL material. Elsewhere, such as on the matrix material between the diamond crystals on the surface of the DL material, the diamond layer will nucleate as typical fine grain polycrystalline diamond. The epitaxial growth of the CVD diamond layer onto the diamond crystals of the DL material forms a very good thermal match to the DL material, avoiding degraded material at the boundary, or poor mechanical contact, or phonon scattering due to poor thermal matching.

The grain size of polycrystalline diamond layers is a concept generally understood by those well versed in the art. Polycrystalline CVD diamond growth is directional and as such it produces columnar grains. The grain size referred to is that determined on a plane normal to the direction of growth. A grain is then a region of material within which the material is generally related in crystallographic orientation, being either the same or related by twinning, and generally surrounded by incoherent boundaries separating it from material whose crystallographic orientation is unrelated. The grain size is the average ‘diameter’ of such grains in the plane normal to growth, the average diameter being obtained by averaging the maximum chord across the grain in a number of different directions. A simple and generally valid approximation is to measure one or more preferably two lateral dimensions of each grain. The grain boundaries of the polycrystalline diamond layer can be revealed by polishing and then applying an etch, such as a chemical etch or a flame etch. In areas of fine grain polycrystalline diamond (e.g. <20-40 μm) this simple procedure may only set an upper limit to the grain size.

Experiments in-house and studies reported in the literature (for instance J. E. Graebner, S. Jin, G. W. Kammlott, J. A. Herb and C. F. Gardinier, “Usually high thermal conductivity in diamond films” Appl. Phys. Lett., Vol. 60 (13), p. 1576, 30 Mar. 1992) have shown that the fine grained polycrystalline diamond material associated with the initial nucleation stages of CVD diamond growth which is randomly nucleated on a non-diamond substrates has a much lower thermal conductivity than the bulk material (more than 50% lower). Example data from the in-house study are:

| Distance from the | Local thermal |
|---|---|
| nucleation surface (μm) | conductivity (W/m K) |
| 0 | 1220 |
| 20 | 1500 |
| 100 | 1970 |
| 200 | 2120 |

Epitaxial growth onto the diamond in a DL material therefore has two thermal advantages over non-epitaxial growth. Firstly the epitaxy ensures that there is a good interface between the DL material and the coating as even minor interfacial problems can be significant thermal barriers, and secondly the CVD diamond layer will itself be of a higher thermal conductivity because it contains a substantially reduced proportion of the low quality fine grain nucleation material.

It has been found that the relative surface area of the DL material which is exposed diamond can be enhanced by a variety of means, as can the method of forming an epitaxial bond between this exposed diamond in the DL material and the CVD diamond layer.

In particular, the epitaxy is preferably enhanced by using such techniques to the point at which one or more of the following is achieved:
1. epitaxial growth by CVD on the diamond loading of the DL material forms a substantial portion of the surface area of the interface between the CVD diamond layer and the DL material, where this substantial portion of the surface area exceeds 30%, or exceeds 40%, or exceeds 50%, or exceeds 60%, or exceeds 70% of the total surface area.
2. CVD diamond grains produced by epitaxial growth on the diamond loading of the DL material form a substantial portion of the surface area of the final growth surface. The lateral dimensions of the CVD diamond grains nucleated on the matrix or otherwise at the interface between the CVD diamond layer and the DL material are generally of the order of the thickness of the layer or less at the growth surface, whereas the lateral dimensions of grains grown epitaxially on the diamond loading of the DL material are generally of the order of the particle size of the diamond loading. Where the CVD diamond layer thickness is substantially smaller, by more than 4 times and preferably by more than 10 times, than the particle size of the diamond loading of the DL material, then a meaningful analysis can be made of the grain size distribution at the growth surface. Using a polish and subsequent etch or other suitable preparation to reveal grain boundaries, the total surface area at the CVD diamond growth surface of grains with one and preferably two lateral dimension exceeding 4 times and more preferably 10 times the diamond layer thickness must cover a substantial portion of the growth surface of the CVD diamond layer when polished, where this substantial portion of the surface area exceeds 30%, or exceeds 40%, or exceeds 50%, or exceeds 60%, or exceeds 70% of the total surface area.
3. the epitaxial diamond grown by CVD on the diamond loading of the DL material forms a substantial portion of the volume of the CVD diamond layer, where this substantial volume exceeds 30%, or exceeds 40%, or exceeds 50%, or exceeds 60%, or exceeds 70% of the volume of the CVD diamond layer.

In material where epitaxy between the CVD diamond layer and the diamond crystals of the DL material has been substantially achieved, particularly in the case where the diamond crystals in the DL material are larger than the thickness of the CVD diamond layer, the above criteria have a substantial similarity. This is because the grain structure of polycrystalline diamond is columnar and only slowly increases in grain size with layer thickness. The particular advantage then of the different criteria is that they may be more easily applicable under certain conditions, and for example that criteria 2 is a less destructive test than criteria 1 and 3.

Preparation of the DL surface prior to growing the CVD diamond layer can for instance include exposure of embedded diamond crystals by lapping the composite material prior to deposition of the CVD diamond layer.

A key problem in processing the surface of the DL material is that the diamond grits are very hard wearing compared to the matrix material. The result is that it is very easy to cause pitting to form in the matrix material during processing of the surface. This pitting is very detrimental because of causing pinholing in the diamond overlayer. The key to solving this pitting problem is to control the diamond grit particle size distribution in the lapping process.

A simple model is that the surface being lapped can be considered to float above the lapping plate at a spacing set by the mean size of the grit particles, so that rogue larger particles then take a significant part of the load applied to the surface being lapped and cause a series of pits until the particles finally break up. In contrast, smaller grits individually do not cause harm, but may reduce the mean grit particle size.

The inventors have shown, over the limited range of grit particle sizes explored, that the grit particle size distribution should be such that compared to the mean grit particle size, the largest grits should preferably be not more than 20% or 15 μm larger, whichever is the most restrictive, and more preferably not more than 10% or 10 μm larger, whichever is the most restrictive. This applies specifically for contact pressures of 0.7 g/mm², and is likely to vary slightly with contact pressure.

Alternatively, or in addition, the diamond loaded composite material can be a graded material, such that the loading density and particle size distribution at the surface is optimised on the basis of one or more of:
a) improving the degree of epitaxy between the CVD diamond layer and the diamond of the DL material;
b) improving the thermal expansion match between the diamond layer and the surface of the DL material,
whilst in the body of the DL material the loading density and particle size distribution may be optimised to other parameters such as bulk thermal conductivity, cost, or matching (both thermal conductivity and thermal expansion coefficient) to the underlying heat sink. The loading particle size distribution may also be optimised according to the intended thickness of the overgrown diamond layer.

As a further alternative, other steps in the preparation and growth conditions for the CVD diamond layer can be optimised for the growth of the epitaxial diamond on the diamond loading of the DL material. In particular, a chemical etch or plasma etch may be used to ensure a clean diamond interface for epitaxial growth, and to modify and control the nucleation density and nucleation time of the fine intergranular diamond nucleation. Control of the latter parameters, and of the relative growth rates of the large epitaxial diamond and fine nucleated diamond (for example by using growth parameters) can be used to control the grain structure of the CVD diamond layer. In addition, the gas composition in the growth process, and in particular the concentration of the carbon source, may be controlled to optimise epitaxy.

A second layer of diamond may be bonded to or grown onto the reverse face of the DL material. This layer may assist in the interface with a subsequent heat sink material. This second layer may also benefit from the range of techniques used to enhance the degree of epitaxy between the diamond layer and the diamond loading of the DL material

Furthermore, the invention also includes the use of a layer of DL material, having major surfaces on opposite sides thereof and a diamond layer in thermal contact with one or both of the major surfaces, for use as a heat spreader material. A particular embodiment is where a device requiring thermal management is mounted or bonded to the outer face of a diamond layer bonded to the DL material using the method of this invention.

The diamond layer in the heat spreader of the invention further provides the heat spreader with sufficient electrical isolation for the mounting of electronic devices, and with a performance as a heat sink which is preferably at least as good as known DL materials and more preferably enhanced over known DL materials.

The diamond layer may be smoothed, planarised or polished and will be in contact with the electronic device or other heat source. The diamond layer may cover an entire surface of the DL material or may cover only specific areas, for example, if the heat spreader is to be used in a multi-chip module.

The DL material will generally be placed in thermal contact with a heat sink such as a metallic heat sink.

The diamond layer and/or the DL material may be metallised or patterned to provide suitable contacts to an electronic device or aid in joining the heat spreader to a heat sink. Holes through the diamond layer and/or DL material may also be provided for electrical interconnection, optical addressing or other purpose. Where the DL material is coated on both sides with diamond, the conductive DL material may be used as a ground plane, or as one of the electrical interconnects to the devices.

The layer of diamond is preferably a layer of CVD diamond grown on a layer of DL material, which is preferably lapped prior to coating with CVD diamond. Generally, the diamond layer will be thin and typically have a thickness of no more than 300 μm. However, the diamond layer thickness will be chosen to provide suitable electrical isolation between the device and the DL material. For example, to hold off 1000V the diamond layer would need to have a thickness of at least 25 μm. The thickness of the diamond layer will also be chosen to ensure that the overall thermal performance of the heat spreader conforms to requirements whilst remaining cost effective.

The CVD diamond may be produced by known methods and is generally polycrystalline.

The heat spreader of the invention has particular application to large electronic devices such as silicon-based devices. For such large devices, the relatively inexpensive heat spreaders such as aluminium nitride are not suitable because of the difference in thermal expansion coefficient between the silicon-based device and aluminium nitride. Diamond has a much closer match, but diamond on its own for such a device would be expensive. The heat spreader comprising a thin diamond layer in thermal contact with a layer of DL material provides an effective heat spreader and electrical isolation at a commercially competitive price. DL materials alone cannot be used in many applications as they all electrically conduct. The CVD diamond layer provides electrical insulation without impairing the thermal conductivity, and generally increases the thermal conductivity in the layer immediately adjacent to the device to be cooled.

The heat spreader of the invention also has particular application to small heat sources for which the thermal contact area to the heat spreader is smaller than the diamond crystallite size in the DL material. Without the CVD diamond coating, the thermal cooling and thus the performance of the device will depend on whether it is sitting on a diamond crystallite or on the lower thermal conductivity filler material between the diamond crystallites. The CVD diamond coating provides a layer of uniform thermal conductivity on which the device can sit and thus ensures that the device performance is reproducible.

The enhanced epitaxy of the diamond layer produced according to the method of this invention increases the thermal conductivity of that diamond layer. This is particularly important since it is the heat spreader layer in closest contact with the device to be cooled. As an example, consider a small electronic device to be cooled (e.g. with characteristic lateral dimensions of the critical thermal contact surface in the range of say 1-20 μm). The optimum thickness of CVD diamond layer is typically only of the order of 1-3 times greater than this characteristic dimension, so 3-60 μm. A randomly nucleated polycrystalline diamond layer would typically have a grain size smaller, often substantially smaller, than this thickness. However using the epitaxy afforded by this invention a substantial proportion by volume of the grains in the CVD diamond layer can be similar to the size of the diamond crystal in the DL layer, which may for example be chosen to be 100-200 μm. The larger grain sized diamond layer then provides a higher thermal conductivity.

### EXAMPLE 1

A microwave plasma CVD synthesis reactor (which is well known in the CVD art) was used to deposit layers of diamond of up to 25 μm onto a DL material consisting of diamond crystallites in a matrix of SiC. The diamond crystallite size in the DL material was in the range 100 to 250 μm.

The surface of the 5 mm×5 mm DL sample was prepared using standard lapidary techniques but with a synthetic diamond grit with a narrow band of particle sizes (325/400, sieve size 45/38 μm) in a water-based suspension. The contact pressure applied was 0.7 g/mm² and the sample was lapped for 1 hour.

The substrate was loaded into the microwave plasma CVD diamond deposition reactor, vacuum established, and then a mix of H₂/Ar in the ratio 3000:40 sccm was introduced. A plasma was established and the pressure increased and stabilised at 200 mBar. A uniform temperature of the surface of the DL material to be coated was then established at 850° C., measured using optical pyrometry and CH₄ was introduced to give a H₂/CH₄ ratio of 3000:40 sccm.

The deposition run was terminated by first switching out the CH₄ and then steadily reducing power and pressure to reduce the substrate temperature to below 450° C. over about a 10 minute period, when the process was terminated.

The CVD diamond layer thickness was found to be 25 μm. Examination of the surface of the CVD diamond revealed well-intergrown crystals of high quality. The adhesion to the substrate material was good, with no signs of delamination or cracking.

The layer was subsequently polished at a shallow angle (7.5°) to the growth surface using standard CVD diamond polishing techniques. Polishing through the coating to the underlying substrate in one portion revealed the interface, showing it to be sharp and of a high quality (no indication of non-diamond carbon phases), the characteristics of the underlying DL material, and the grain size of the CVD diamond coating as a function of depth. Visual identification of these features could be enhanced by a variety of standard etching techniques. Throughout the thickness of the CVD diamond layer the dominant grain size was −200 μm, i.e. matching the grain size of the underlying DL material. The portion of the growth surface covered by grains of this size (−8 times the layer thickness) was 76%. For this thickness of coating and this grain size, the grain shape does not change significantly through the layer, so that the volume of epitaxial CVD diamond with this grain size is also ˜76%.

### COMPARATIVE EXAMPLE 1

For comparison, a 5×5 mm sample was coated using the same procedure as Example 1 and on the same type of DL material (particle size 100 to 250 μm) but without the lapidary preparation stage. The final coating thickness on this sample was 22 μm.

The sample was polished at a shallow angle in the same manner as in Example 1 to reveal the interface quality and coating grain structure. The quality of the interface was once again good, but the dominant CVD diamond grain size adjacent to the interface was less than 10 μm increasing to less than 40 μm on the surface. This is a clear indication that there has been far less epitaxial growth in this sample (possibly none) than in Example 1. There was also evidence of pitting/pinholing in the coating penetrating through to the underlying substrate material. This is believed to result from pitting present in the initial surface of the DL material.

### EXAMPLE 2

A 10 mm×10 mm DL sample was coated using the procedure given in Example 1. The CVD diamond was then polished back to give a coating with a uniform thickness of 10 μm.

The polished layer was transparent and colourless and the features of the underlying substrate were clearly visible. This demonstrates that both the CVD diamond layer and the interface between the diamond layer and the DL material were of high quality. The grain structure of the polished CVD diamond layer (revealed by etching) maps perfectly onto the underlying DL material grain structure, confirming the epitaxial nature of the growth. The proportion of the final CVD diamond layer surface resulting from grains grown epitaxially on the underlying diamond crystals exposed at the surface of the DL material is >90% in this case. This suggests that, having formed a substantial proportion of epitaxial crystals at the interface, these compete well against the fine grained polycrystalline material nucleated on the matrix of the DL material as the layer grows thicker. When the surface roughness of the polished layer was assessed using a Taylor Hobson “Form Talysurf50” system an Ra value of 8 nm was obtained. No holes could be detected on the coating using microscopy at x50 magnification indicating that the coating would have good electrical isolation properties.

### EXAMPLE 3

A 50 mm Ø DL sample was coated with CVD diamond using the procedure in Example 1 but to a thickness of 250 μm. Once again the adhesion was good, there being no signs of delamination or fracture. The sample was polished and then a 25 mm Ø sample was laser cut from its centre using standard CVD diamond laser cutting techniques as widely reported in the literature. The laser cut edge was of high quality and there was no evidence of delamination at, or near, the cut. Nor was an interface between the coating and the DL material apparent on the cut face.

1-38. (canceled)

39. A heat spreader comprising:
a layer of CVD diamond grown onto a diamond loaded (DL) material, the DL material comprising a mass of diamond particles in a matrix and having a surface with exposed diamond particles on which the layer of CVD diamond is grown,
wherein the layer of CVD diamond is bonded to the exposed diamond particles of the DL material at least in part by epitaxy.

40. A heat spreader according to claim 39, wherein the layer of CVD diamond is continuous and without uncontrolled pits or holes.

41. A heat spreader according to claim 39, which exhibits substantial epitaxy at an interface between the layer of CVD diamond and the exposed diamond particles of the DL material.

42. A heat spreader according to claim 41, wherein the epitaxy covers an area of the interface exceeding 30%.

43. A heat spreader according to claim 42, wherein the epitaxy covers an area of the interface exceeding 50%.

44. A heat spreader according to claim 43, wherein the epitaxy covers an area of the interface exceeding 60%.

45. A heat spreader according to claim 44, wherein the epitaxy covers an area of the interface exceeding 70%.

46. A heat spreader according to claim 39, wherein the grown layer of CVD diamond has an exposed surface with at least 30% of the exposed surface being occupied by diamond grains with a grain size of at least four times a thickness of the layer of CVD diamond.

47. A heat spreader according to claim 46, wherein the diamond grains occupy at least 50% of the exposed surface of the layer of CVD diamond.

48. A heat spreader according to claim 47, wherein the diamond grains occupy at least 60% of the exposed surface of the layer of CVD diamond.

49. A heat spreader according to claim 48, wherein the diamond grains occupy at least 70% of the exposed surface of the layer of CVD diamond.

50. A heat spreader according to claim 39, wherein the layer of CVD diamond comprises epitaxial diamond grains that provide at least 30% of the volume of the layer of CVD diamond.

51. A heat spreader according to claim 50, wherein the epitaxial diamond grains provide at least 50% of the volume of the layer of CVD diamond.

52. A heat spreader according to claim 51, wherein the epitaxial diamond grains provide at least 70% of the volume of the layer of CVD diamond.

53. A heat spreader according to claim 39, wherein the DL material is provided in a form of a layer with the layer of CVD diamond being grown on a major surface of the layer of DL material.

54. A heat spreader comprising:
a layer of DL material having major surfaces on each of opposite sides thereof; and
a layer of CVD diamond in thermal contact with each of the major surfaces, with either one or both of the CVD diamond layers being bonded at least in part by epitaxy to exposed diamond particles of the DL material.

55. A heat spreader according to claim 39, wherein the bonding by epitaxy between the layer of CVD diamond and the exposed diamond particles of the DL material is deliberately enhanced over that which might occur naturally using untreated, DL material.

56. A heat spreader according to claim 54, wherein the bonding by epitaxy between the layer of CVD diamond and the exposed diamond particles of the DL material is deliberately enhanced over that which might occur naturally using untreated. DL material.

57. A method of manufacturing a heat spreader comprising:
providing a diamond loaded (DL) material comprising a mass of diamond particles in a matrix and having an exposed surface with exposed diamond particles;
growing a layer of CVD diamond onto the exposed surface of the DL material such that it is bonded to the exposed diamond particles at least in part by epitaxy,
wherein the exposed surface of the DL material is treated prior to growing the layer of CVD diamond thereon, thereby to enhance the epitaxy over that which would otherwise occur naturally using untreated DL material.

58. A method according to claim 57, wherein the exposed surface of the DL material is treated by a lapping process.

59. A method according to claim 55, wherein the lapping process is arranged to remove existing pitting, minimize further surface pitting, and maximize a surface area of the exposed diamond particles present in the exposed surface of the DL material suitable for epitaxy.

60. A method according to claim 59, wherein the surface pitting is removed and further pitting minimized by controlling diamond particle size distribution in the lapping process.

61. A method according to claim 60, wherein the lapping process is carried out in such a manner as to ensure that largest diamond particles are not more than 20% or 15 μm larger, whichever is most restrictive, than a mean particle size of the diamond particles in the exposed surface of the DL material.

62. A method according to claim 61, wherein the largest diamond particles are not more than 10% or 10 μm larger, whichever is the most restrictive, than the mean particle size of the diamond particles in the exposed surface of the DL material.

63. A method according to claim 57, wherein the layer of CVD diamond is continuous and without uncontrolled pits or holes.

64. A method according to claim 57, which exhibits substantial epitaxy at an interface between the layer of CVD diamond and the exposed diamond particles of the DL material.

65. A method according to claim 64, wherein the epitaxy covers an area of the interface exceeding 30%.

66. A method according to claim 65, wherein the epitaxy covers an area of the interface exceeding 50%.

67. A method according to claim 66, wherein the epitaxy covers an area of the interface exceeding 60%.

68. A method according to claim 67, wherein the epitaxy covers an area of the interface exceeding 70%.

69. A method according to claim 57, wherein the grown layer of CVD diamond has an exposed surface with at least 30% of the exposed surface being occupied by diamond grains with a grain size of at least four times a thickness of the layer of CVD diamond.

70. A method according to claim 69, wherein the diamond grains occupy at least 50% of the exposed surface of the layer of CVD diamond.

71. A method according to claim 70, wherein the diamond grains occupy at least 60% of the exposed surface of the layer of CVD diamond.

72. A method according to claim 71, wherein the diamond grains occupy at least 70% of the exposed surface of the layer of CVD diamond.

73. A method according to claim 57, wherein the layer of CVD diamond comprises epitaxial diamond grains that provide at least 30% of the volume of the layer of CVD diamond.

74. A method according to claim 73, wherein the epitaxial diamond grains provide at least 50% of the volume of the layer of CVD diamond.

75. A method according to claim 74, wherein the epitaxial diamond grains provide at least 70% of the volume of the layer of CVD diamond.

76. A method according to claim 57, wherein the DL material is provided in a form of a layer and the layer of CVD diamond is grown on a major surface of the layer of DL material.

77. A method according to claim 76, wherein opposed layers of CVD diamond are grown on respective opposed major surfaces of the layer of DL material, either one or both of the layers of CVD diamond being bonded at least in part by epitaxy to expose diamond particles of the DL material.
